(19) United States
(12) Patent Application Publication
(10) Pub. No.: US 2006/0003556 A1
(43) Pub. Date: Jan. 5, 2006

(54) Method of growing semi-insulating GaN layer

(75) Inventors: Jae Hoon Lee, Suwon (KR); Jung Hee Lee, Daegu (KR)

Correspondence Address: LOWE HAUPTMAN GILMAN AND BERNER, LLP, 1700 DIAGONAL ROAD, SUITE 300 /310, ALEXANDRIA, VA, 22314, US

(73) Assignee: Samsung Electro-Mechanics Co., Ltd., Suwon (KR)

(21) Appl. No.: 10/965,263

(22) Filed: Oct. 15, 2004

(30) Foreign Application Priority Data
Jul. 5, 2004 (KR) 2004-51983

(51) Int. Cl. H01L 21/20

(52) U.S. Cl. 438/483; 438/493

(57) ABSTRACT

Disclosed herein is a method for growing a semi-insulating GaN layer with high sheet resistance by controlling the size of grains through changes in growth temperature at the initial growth stage of the layer, without doping of dopants. The method comprises the steps of growing a buffer layer on a substrate at a first growth temperature, growing a GaN layer on the buffer layer at a second growth temperature higher than the first growth temperature for a first growth time (a first growth step), growing the GaN layer at increasing temperatures from the second growth temperature to a third growth temperature higher than the second growth temperature for a second growth time (a second growth step), and growing the GaN layer at the third growth temperature for a third growth time (a third growth step).

### RELATED APPLICATIONS

The present application is based on, and claims priority from, Korean Application Number 2004-51983, filed Jul. 5, 2004, the disclosure of which is hereby incorporated by reference herein in the entirety.

### BACKGROUND OF THE INVENTION

1. Field of the Invention

The present invention relates to a method for growing a semi-insulating undoped GaN layer, and more particularly to a method for growing an undoped GaN layer with high sheet resistance by controlling the size of grains through changes in growth temperature at the initial growth stage of the layer, without doping of dopants.

2. Description of the Related Art

With the recent development of digital communication technologies, communication technologies for ultrahigh-speed and high-capacity signal transmission have been rapidly advanced. In particular, as the demands on personal cellular phones, satellite communications, military radars, broadcasting communications, communication satellites, and the like have been increased in wireless communication technologies, there is an increasing need for high-speed and high-power electronic devices essential to ultrahigh-speed digital communication systems in the microwave and millimeter-wave bands. Since GaN as a nitride semiconductor material has superior physical properties, e.g., large energy gap, superior thermal and chemical stability, high electron saturation velocity (˜3×10⁷ cm/sec), etc., it has strong potential for application to optoelectronic and high-frequency and high-power electronic devices. A number of studies on GaN are being actively undertaken in various fields.

In particular, it is widely known that GaN has various applications in the field of electronic devices.

Electronic devices fabricated employing GaN have many advantages in terms of a high breakdown voltage (˜3×10⁶ V/cm), maximum current density, stable high temperature operation, high thermal conductivity, etc. Since heterostructure field effect transistors (HFETs) fabricated using an AlGaN/GaN heterojunction structure have large band-discontinuity at the junction interface, a high concentration of free electrons may be present at the interface and thus the electron mobility is further increased. Further, since the GaN layer has a high surface-acoustic-wave velocity, superior temperature stability and polarization effects of piezoelectricity, it can be easily used for the fabrication of a band-pass filter which can be operated on the order of GHz or more.

As such, the GaN layer used in electronic devices, for example, HFETs and surface acoustic wave (SAW) devices, is commonly grown on a sapphire substrate by metal-organic chemical vapor deposition (MOCVD) or molecular beam epitaxy (MBE). However, since there is a large difference in the lattice constant and thermal expansion coefficient between the sapphire substrate and the GaN layer, the growth of a single crystal is difficult and many defects are generated during growth of the layer. In addition, nitrogen vacancies are formed due to highly volatile nitrogen. Furthermore, since n-type conductivity naturally takes place due to the influence of impurities, such as oxygen, it is difficult to form a semi-insulating layer. For these reasons, a leakage current is caused during fabrication of electronic devices, such as HFETs and SAW devices, leading to low transconductance and increased insertion loss.

FIG. 1 shows the procedure of a conventional method for growing a semi-insulating GaN layer.

Referring to FIG. 1, a conventional semi-insulating GaN layer is grown in accordance with the following procedure. First, a sapphire substrate is subjected to cleaning at a temperature of 1,000° C. or higher, and then a buffer layer is formed thereon at a low temperature of about 550° C. (I). The formation of the buffer layer serves to decrease the lattice constant and thermal expansion coefficient between the sapphire substrate and a GaN layer to be grown. Thereafter, after the growth temperature is raised to 1000° C.˜1,100° C. for a given time, the GaN layer is grown (II). In order to remove naturally occurring n-type conductivity during the growth of the conventional highly resistive GaN layer, dopants, such as Zn, Mg, C and Fe, are doped. However, the dopants may remain in a chamber where the GaN layer is grown, resulting in doping into unwanted layers, i.e., memory effect. Further, when the temperature is increased with the flow of an electric current upon operation of a device, hydrogen atoms (H) bound to Mg and Zn are activated and the GaN layer becomes conductive. This conductive GaN layer cannot ensure sufficient insulation between devices, causing malfunction of the devices. Further, doping of high-concentration dopants leads to degraded crystallinity and adversely affects the performance of the devices.

### SUMMARY OF THE INVENTION

Therefore, the present invention has been made in view of the above problems of the prior art, and it is an object of the present invention to provide a method for growing a semi-insulating GaN layer with high sheet resistance by controlling the size of grains through changes in growth temperature at the initial growth stage of the layer, without doping of dopants such as Zn, Mg, C, Fe, etc.

In order to accomplish the above object of the present invention, there is provided a method for growing a semi-insulating GaN layer, comprising the steps of: growing a buffer layer on a substrate at a first growth temperature; growing a GaN layer on the buffer layer at a second growth temperature higher than the first growth temperature for a first growth time (a first growth step); growing the GaN layer at increasing temperatures from the second growth temperature to a third growth temperature higher than the second growth temperature for a second growth time (a second growth step); and growing the GaN layer at the third growth temperature for a third growth time (a third growth step).

It is preferable that the second growth temperature is in the range of about 800° C. to about 950° C/, and the third growth temperature is in the range of about 1,000° C. to 1,100° C.

Further, it is preferable that the first growth time is about 3 minutes or less, and the second growth time is about 5 minutes or less.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a time-temperature graph showing the procedure of a conventional method for growing a semi-insulating GaN layer;

FIG. 2 is a time-temperature graph showing the procedure of a method for growing a semi-insulating GaN layer according to the present invention;

FIGS. 3a to 3d are scanning electron microscopy (SEM) and atomic force microscopy (AFM) images showing the surface state of low-temperature buffer layers at various temperatures;

FIG. 4 is a graph showing HR-XRD data measured after buffer layers grown on respective sapphire substrates were annealed at various temperatures;

FIG. 5 shows photoluminescence (PL) spectra taken after buffer layers grown to a thickness of 160 Å at 550° C. on respective sapphire substrates were annealed at temperatures of 950° C., 1,020° C. and 1,050° C., respectively, for 4 minutes;

FIG. 6 is a graph showing the mobility and sheet resistance of GaN layers grown at different temperatures, as determined by Hall measurement;

FIGS. 7a to 7e are AFM and SEM images of GaN layers grown at different temperatures;

FIG. 8a shows SEM and AFM images of the surface of a GaN layer grown by a conventional method, and FIG. 8b shows SEM and AFM images of the surface of a GaN layer grown by the method of the present invention;

FIG. 9a shows PL spectra of GaN layers grown for 3 minutes by a conventional method and a method of the present invention, respectively; FIG. 9b is PL spectra of GaN layers grown for 40 minutes by a conventional method and a method of the present invention, respectively;

FIG. 10 is a cross-sectional view of an HFET to which a GaN layer grown by a method of the present invention can be applied;

FIG. 11 is a top view of a SAW device to which a GaN layer grown by a method of the present invention can be applied; and

FIG. 12a is a graph showing the frequency response characteristics of a SAW device fabricated using a GaN layer grown by a conventional method, and FIG. 12b is a graph showing the frequency response characteristics of a SAW device fabricated using a GaN layer grown by a method of the present invention.

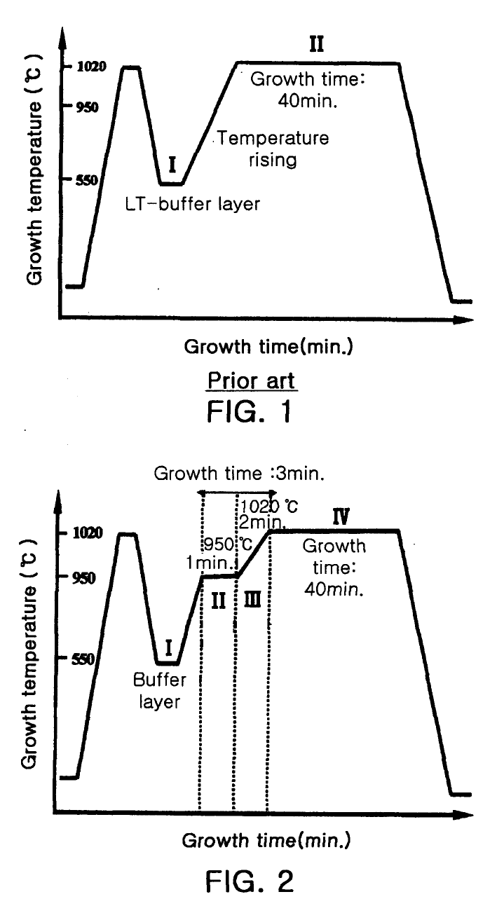

### DESCRIPTION OF THE PREFERRED EMBODIMENTS

A method for growing a semi-insulating GaN layer according to the present invention will now be described in more detail with reference to the accompanying drawings.

FIG. 2 is a growth time-growth temperature graph showing the procedure of a method for growing a semi-insulating GaN layer according to the present invention. Referring to FIG. 2, a buffer layer is grown on a sapphire substrate at a first growth temperature (I). Since there is no substrate having a lattice constant and a thermal expansion coefficient identical to those of GaN as a nitride semiconductor material, it is common that a buffer layer is previously grown on a sapphire substrate. In order to reduce the difference in the lattice constant and thermal expansion coefficient between the sapphire substrate and a nitride semiconductor material to be grown thereon, and to prevent the degradation of crystallinity, the buffer layer is preferably formed to a small thickness at low temperature. The buffer layer is grown in a chamber by metal-organic chemical vapor deposition (MOCVD) or molecular beam epitaxy (MBE) at a first growth temperature (about 550° C.), which is the inner temperature of the chamber.

After the formation of the buffer layer, the first growth temperature is increased to a second growth temperature. At this temperature, a GaN layer is grown on the buffer layer for a first growth time (II, hereinafter referred to as ‘a first growth step’). It is preferable that the buffer layer is subjected to annealing at the second growth temperature for several minutes, before the growth of the GaN layer on the buffer layer at the second growth temperature. The second growth temperature is a temperature at which the size of grains present in the buffer layer is relatively small and the density of grains is high. The second growth temperature is lower than the growth temperatures of conventional GaN layers. By growing the GaN layer on the buffer layer having relatively small and highly dense grains formed thereon at the second growth temperature, Ga vacancies capable of capturing electrons, acting as carriers, are formed. Relatively large grains are formed at a growth temperature (about 1,000° C.˜1,100° C.) of a conventional GaN layer, and thus Ga vacancies capable of capturing electrons are seldom formed. These uncaptured electrons act as carriers, causing the degradation of insulation. The second growth temperature for forming small-sized grains is preferably in the range of about 800° C. to 950° C.

It is preferable that the first growth time is relatively short. This is because the degradation of crystallinity is caused by the GaN layer grown on the buffer layer having relatively small and highly dense grains formed thereon. The first growth time is preferably 3 minutes or shorter.

After the first growth step is completed, the GaN layer is grown while the temperature is increased to a third growth temperature higher than the second growth temperature (III, hereinafter referred to as ‘a second growth step’). While the small and highly dense grains are formed at the initial stage of the first growth step, the GaN layer is grown at the first growth step for a relatively short time, and the growth temperature is increased to a third growth temperature, defects associated with Ga vacancies are formed. The presence of these defects leads to the formation of a larger number of deep trap levels capable of capturing free electrons, acting as carriers, in the GaN band gap. Specifically, when the free electrons are captured by the Ga vacancies, the number of active carriers in the GaN layer is reduced, and finally the GaN layer exhibits semi-insulation. To attain better semi-insulation of the GaN layer, the second growth time is preferably 5 minutes or less.

After the second growth step is completed, the GaN layer is grown to a desired thickness while maintaining the third growth temperature to form the final semi-insulating GaN layer.

In order to develop the method for growing a semi-insulating GaN layer according to the present invention, the present inventors have conducted the following experiment. Hereinafter, the experimental results will be explained in more detail with reference to the accompanying drawings.

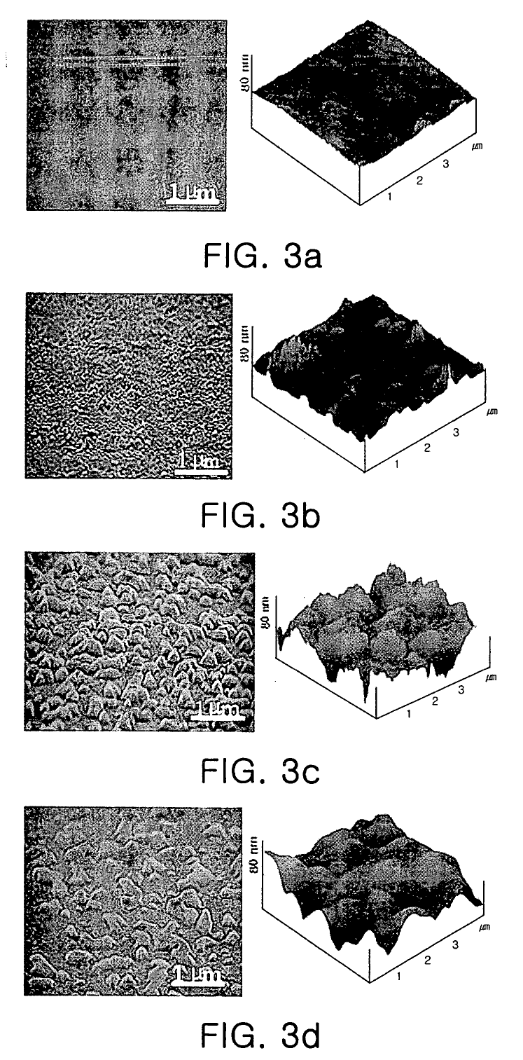

FIGS. 3a to 3d are SEM and AFM images showing the surface state of low-temperature buffer layers at various temperatures. Specifically, FIGS. 3a, 3b, 3c and 3d show the surface state of low-temperature buffer layers at 550° C., 950° C., 1,020° C. and 1,050° C., respectively. First, four low-temperature buffer layers were grown to a desired thickness on respective sapphire substrates, and then the temperatures of the buffer layers were raised to 950° C., 1020° C. and 1050° C. within 4 minutes, respectively. At the respective temperatures, SEM and AFM images of the low-temperature buffer layers were taken. The root mean square (RMS) for the surface roughness (hereinafter, referred to as “RMS roughness”) of the low-temperature buffer layer at 550° C. was 2.4 nm. The RMS roughness values of the low-temperature buffer layers annealed at 950° C., 1,020° C. and 1,050° C. were 7.1 nm, 22 nm and 24 nm, respectively.

As is apparent from the SEM images shown in FIGS. 3a to 3d, the annealed low-temperature buffer layers had higher RMS roughness values than the unannealed one, and the low-temperature buffer layers annealed at higher temperatures had higher RMS roughness values. It appears that these observations are because crystal nuclei present on the initial amorphous surface of the low-temperature buffer layers are modified with increasing annealing temperatures, leading to an increase in the RMS roughness. As shown in FIG. 3a, since very small and uniform grains are formed on the surface of the low-temperature buffer layer grown to a relatively thin thickness (160 Å) at 550° C., the surface is smooth. More Ga atoms migrate into the surface of the respective sapphire substrates with increasing annealing temperatures. At this time, the small grains begin to form nucleation sites and agglomerate to form polycrystals having poly-shaped grain boundaries. Since the low-temperature buffer layers have a relatively small thickness, group III elements can be rapidly moved with increasing temperatures, resulting in large grain size and low grain density per unit area.

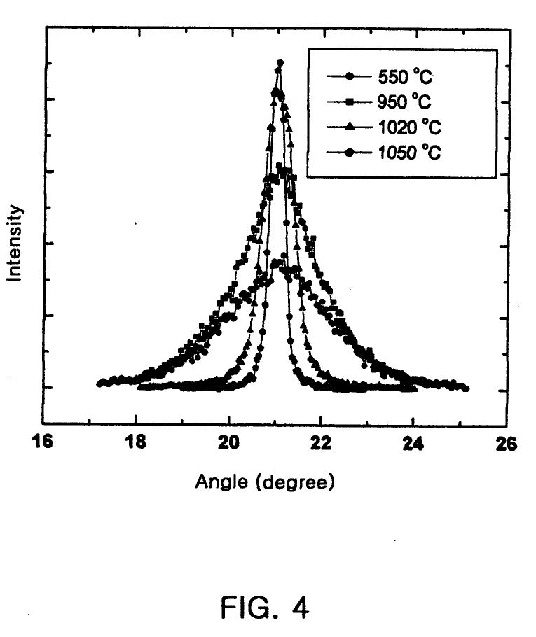

FIG. 4 is a graph showing HR-XRD data measured after buffer layers grown to a thickness of 160 Å at 550° C. on respective sapphire substrates were annealed at temperatures of 950° C., 1,020° C. and 1,050° C., respectively, for 4 minutes. The full width half maximum (FWHM) value of the buffer layer grown at 550° C. was 13786 arcsec, which suggests that the buffer layer is in an amorphous state. When the annealing temperature was increased from 950° C. to 1,050° C., the FWHM value decreased from 8420 arcsec to 2310 arcsec. Since the buffer layer annealed at 950° C. exists in a partially amorphous state, similarly to the buffer layer grown at 550° C., it has a high FWHM value. When the annealing temperature was 1,000° C. or higher, the crystallinity was improved due to the sufficient thermal energy.

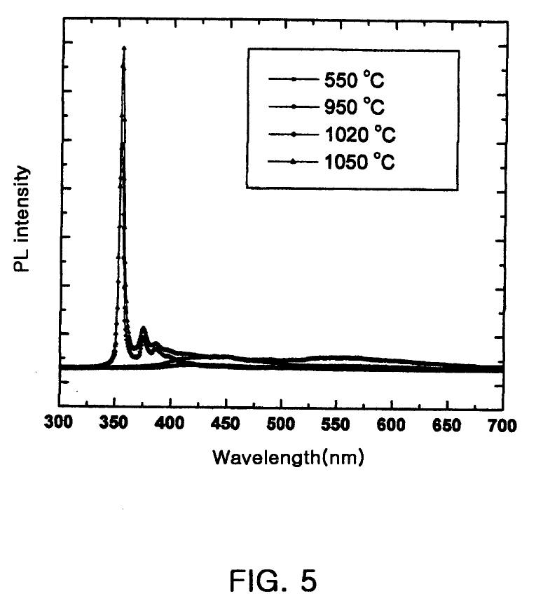

FIG. 5 shows photoluminescence (PL) spectra taken after buffer layers grown to a thickness of 160 Å at 550° C. on respective sapphire substrates were annealed at temperatures of 950° C., 1,020° C. and 1,050° C., respectively, for 4 minutes. As shown in FIG. 5, as the annealing temperature was increased, the PL intensity also increased. The PL intensity of the buffer layer annealed at 950° C. is broadly distributed between 345 nm and 380 nm, like that of the buffer layer grown at 550° C. These results indicate that the buffer layer annealed at 950° C. is in an amorphous state, as was shown in the results of the previous XRD measurement. As the temperature was increased, the GaN band-to-band emission intensity at 365 nm increased. These results show that the buffer layers had better crystallinity, and hence the optical properties were improved.

As can be seen from the results of FIGS. 3 to 5, the grains present on the surface of the low-temperature buffer layers became large and less dense, with increasing temperatures. The large, less dense and crystalline grains can improve the crystallinity of the overlying GaN layer, but less Ga vacancies capable of capturing electrons are formed in the GaN layer, leading to high carrier concentration. Accordingly, the GaN layer is conductive. From the experimental results of FIGS. 3 to 5, it can be concluded that the low-temperature buffer layers annealed at about 950° C. or lower have many Ga vacancies capable of capturing electrons.

In order to evaluate the characteristics of the GaN layers, the present inventors have further conducted the following experiment. First, low-temperature buffer layers were grown to a thickness of 160 Å on respective sapphire substrates. Then, after the growth temperature was increased to 950° C., 980° C., 1,000° C., 1,020° C. and 1,050° C., GaN layers were grown to a thickness of 1.7 μm on the respective sapphire substares for about 40 minutes.

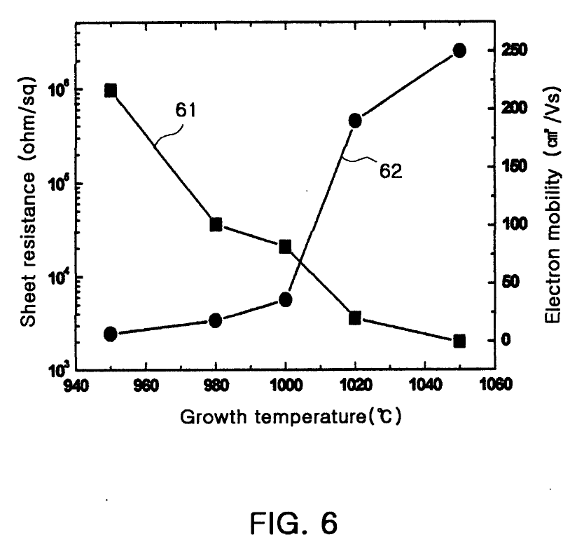

FIG. 6 is a graph showing the mobility and sheet resistance of GaN layers grown at different temperatures, as determined by Hall measurement. As shown in FIG. 6, as the growth temperature of the GaN layers was increased, the electron mobility of the GaN layers increased, but the sheet resistance decreased. In contrast, as the growth temperature was decreased, the sheet resistance greatly increased from 2.0×10³ Ω/sq to 9.7×10⁵ Ω/sq and the electron mobility sharply decreased from 250 cm²/Vs to 6.7 cm²/Vs. Referring again to FIG. 3b, since small and highly dense grains were formed at a growth temperature of 950° C., a columnar buffer layer was predominantly grown and thus a number of defects generated. It is believed that these defects account for an increase in the sheet resistance of the GaN layer. On the contrary, since group III elements freely migrate at higher growth temperatures, polycrystals having very large grain boundaries were formed, as shown in FIGS. 3c and 3d. Accordingly, it is believed that since the formation of polycrystals leads to a small grain density per unit area, reduced defect density, and decreased sheet resistance, the electron mobility increases.

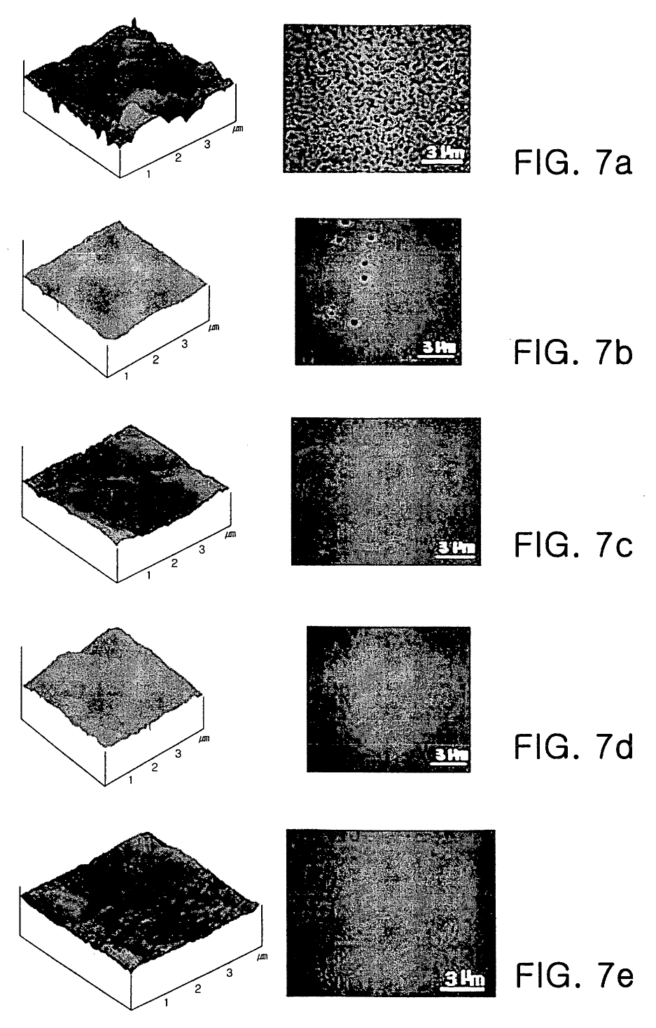

FIGS. 7a to 7e are AFM and SEM images of GaN layers grown at different temperatures of 950° C., 980° C., 1,000° C., 1,020° C. and 1,050° C., respectively. In the case where the growth temperature of the GaN layer was above 1,000° C., substantially smooth surface was attained. Meanwhile, since pyrolysis of TMGa and NH₃ as sources of Ga and N did not occur below 1,000° C., growth in lateral directions was not progressed. As the growth temperature was decreased, the RMS roughness increased from 0.2 nm to 20 nm. The GaN layer grown at 950° C. had a sheet resistance as high as ˜10⁶ Ω/sq, but did not completely grow into crystals. Accordingly, there is a need for increasing the surface roughness.

Thus, the growth procedure of a semi-insulating GaN layer shown in FIG. 2 can be used to increase the surface roughness through sufficient crystal growth while maintaining high sheet resistance. Based on the growth procedures first, a buffer layer was formed at a low temperature (550° C.). Then, after the growth temperature was increased to 950° C., a GaN layer was grown on the buffer layer at this temperature for 1 minute. Thereafter, while the growth temperature was increased to about 1,020° C. for 2 minutes, the GaN layer was further grown. The GaN layer was finally grown to a desired thickness while the temperature was maintained at 1,020° C. By the method of the present invention, a semi-insulating GaN layer completely grown in lateral directions and having a sheet resistance of 1×10⁹ Ω/sq or higher could be grown. The GaN layer grown by the method of the present invention had a higher resistance than the GaN layer grown at 950° C. This is because the formation of very small and highly dense grains at the initial growth stage of 950° C., and further growth of the GaN layer at increasing temperatures cause the generation of defects associated with Ga vacancies. The presence of these defects leads to the formation of a larger number of deep trap levels capable of capturing free electrons in the GaN band gap, contributing to the increase in the sheet resistance of the GaN layer.

The present inventors have compared the initial growth stage of GaN layers grown by a conventional method and the method of the present invention. According to the conventional method, after a buffer layer was grown, a GaN layer was grown on the buffer layer at an increased temperature of 1,020° C. for 3 minutes. In contrast, the method of the present invention was performed as follows: first, a low-temperature buffer layer was grown. Then, after the temperature was increased to 950° C., a GaN layer was grown at this temperature for 1 minute. Thereafter, the GaN layer was further grown while the temperature was increased to 1,020° C. for 2 minutes. The GaN layer was finally grown while the temperature was maintained at 1,020° C.

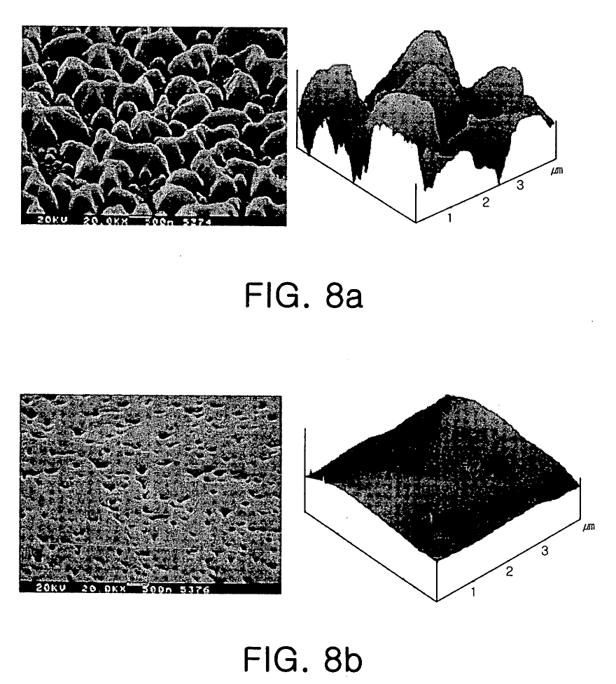

FIG. 8a shows SEM and AFM images of the surface of the GaN layer grown by the conventional method, and FIG. 8b shows SEM and AFM images of the surface of the GaN layer grown by the method of the present invention. As evident from FIG. 8a, the GaN layer grown by the conventional method had a larger grain size than the GaN layer shown in FIG. 3c, and was grown in a horizontal direction. In the GaN layer grown by the method of the present invention, small grains were formed on the surface of the low-temperature buffer layer at the initial low temperature, and then vacancies between the small grains were filled at the initial growth stage for 1 minute, enabling uniform growth in horizontal and vertical directions and thus promoting lateral growth. Further, the GaN layer grown by the conventional method had an RMS roughness of about 7.1 nm, whereas the GaN layer grown by the method of the present invention had an RMS roughness of 2.67 nm. This demonstrates that the GaN layer grown by the method of the present invention had a planar surface at the initial stage for 3 minutes, compared to the GaN layer grown by the conventional method.

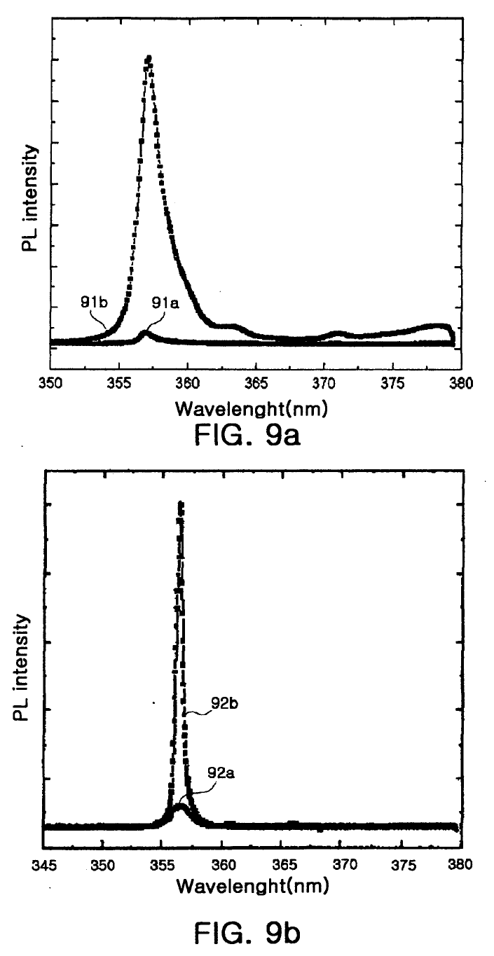

FIG. 9a shows PL spectra of GaN layers grown for 3 minutes by the conventional method and the method of the present invention, respectively; FIG. 9b is PL spectra of GaN layers grown for 40 minutes by the conventional method and the method of the present invention, respectively. As shown in FIG. 9a, the GaN layer grown by the conventional method exhibited a high PL intensity (91b) at the initial growth stage (3 min.), but the GaN layer grown by the method of the present invention exhibited a low PL intensity (91a). This is because the GaN layer grown by the method of the present invention has many defects, such as Ga vacancies, resulting in low band-to-band emission intensity. That is, the high PL intensity of the GaN layer grown by the conventional method is due to the presence of a large quantity of free carriers in the GaN layer, causing the degradation of insulation. In contrast, the low PL intensity of the GaN layer grown by the method of the present invention is due to the presence of few free carriers, indicating that the GaN layer is highly resistive and semi-insulating. This profile was observed in the GaN layers grown for 40 minutes by the conventional method and the method of the present invention (FIG. 9b). These experimental results reveal that the high resistance of the GaN layer grown by the method of the present invention is determined at the initial growth stage.

As explained above, the semi-insulating GaN layer grown by the method of the present invention has various applications in electronic devices requiring semi-insulation. In particularly, the semi-insulating GaN layer grown by the method of the present invention can be widely used in electronic devices having a heterojunction structure. The term “heterojunction structure” refers to one in which materials at different energy levels are joined so that electrons can be stored therein. Representative electronic devices having a heterojunction structure are heterojunction field-effect transistors (HFETs), metal semiconductor field effect transistors (MESFETs), metal insulator semiconductor field effect transistors (MISFETs), and the like. Further, since the GaN layer has piezoelectric effects and high wave propagation velocity along the surface, it is suitably used as a material for surface acoustic wave (SAW) devices which can be used in the high-frequency region.

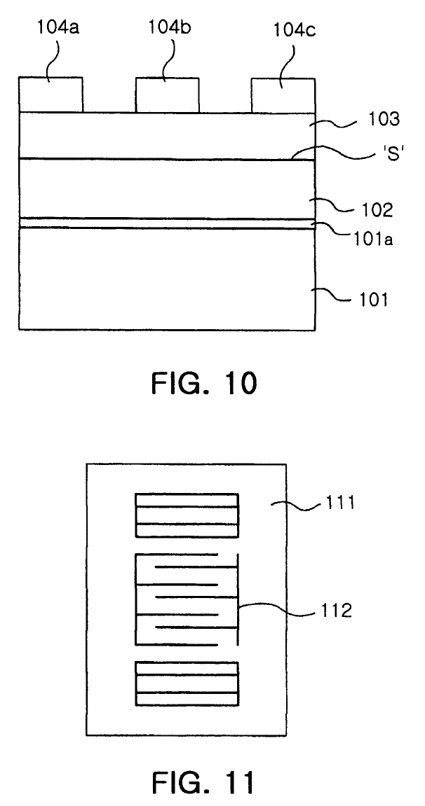

FIG. 10 is a cross-sectional view of an HFET to which the GaN layer grown by the method of the present invention can be applied. The HFET shown in FIG. 10 is fabricated by growing a low-temperature buffer layer 101a on a sapphire substrate 101, growing a semi-insulating GaN layer 102 on the buffer layer 101, growing an AlGaN layer 103 on the semi-insulating GaN layer, and forming a drain electrode 104a, a gate electrode 104b and a source electrode 104c on the AlGaN layer 103. A well is formed at the interface between the semi-insulating GaN layer 102 and the AlGaN layer 103 due to the difference in the energy levels of the GaN layer and the AlGaN layer, and free electrons migrate from the AlGaN layer at a higher energy level to the GaN layer at a lower energy level. An electron gas layer where many free electrons are crowded is formed at the interface between the AlGaN and GaN layers. When an electric voltage is applied between the drain electrode 104a and the source electrode 104c, an electric current flows from the drain electrode 104a to the source electrode 104c through the electron gas layer. If the GaN layer has poor insulation, the current may flow into the GaN layer, which is called a “leakage current”. The leakage current decreases the gain of the HFET. Accordingly, the use of the semi-insulating GaN layer grown by the method of the present invention enables fabrication of HFETs having superior electrical properties.

Metal semiconductor field effect transistors (MESFETs) employ a high concentration n-doped GaN layer, instead of the AlGaN layer employed in the HEETs. Only when there is no leakage current flowing from the high concentration n-doped GaN layer to the underlying insulating GaN layer can MESFETs having superior electrical properties be fabricated.

Further, metal insulator semiconductor field effect transistors (MISFETs) have a structure wherein an insulating layer, such as a SiO₂ layer, is interposed between the AlGaN layer and the gate electrode of the HFET. Like HFETs and MESFETs, only when there is no leakage current flowing into the insulating GaN layer can MISFETs having superior electrical properties be fabricated.

FIG. 11 is a top view of a SAW device to which the GaN layer grown by the method of the present invention can be applied. The SAW device shown in FIG. 11 can be fabricated by forming an IDT 112, acting as a metal electrode, on a piezoelectric substrate 111. Since the GaN layer has piezoelectric effects and high wave propagation velocity along the surface, it can be used as a material for surface acoustic wave (SAW) devices suitable for use in the high-frequency region. In order to use the GaN layer as a material for a piezoelectric substrate of SAW devices, leakage current must not flow into the substrate in a process where an electric signal is converted to a surface acoustic wave, and then the surface acoustic wave is again converted to the electric signal. Namely, in order to use the GaN layer as a material for a piezoelectric substrate of SAW devices, it is preferable that the GaN layer has superior insulation. The semi-insulating GaN layer grown by the method of the present invention is suitably used as a piezoelectric substrate of SAW devices.

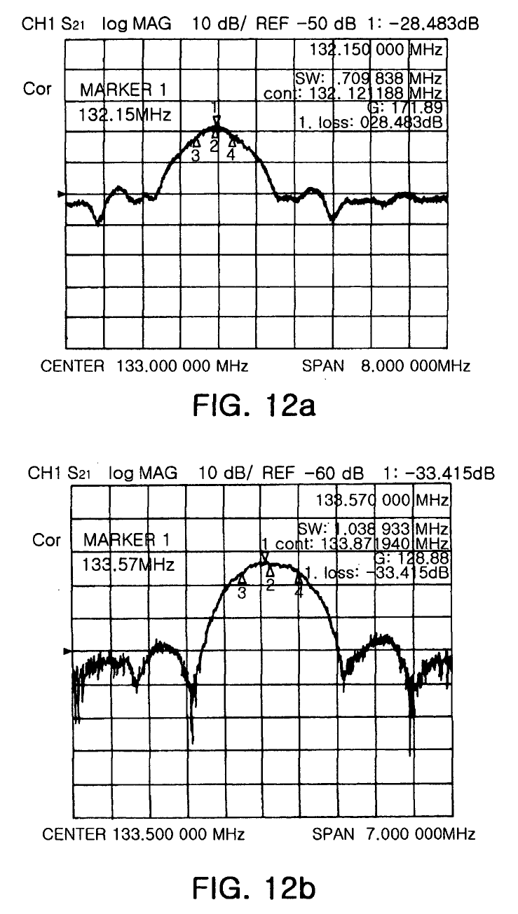

FIG. 12a is a graph showing the frequency response characteristics of a SAW device fabricated using the GaN layer grown by the conventional method, and FIG. 12b is a graph showing the frequency response characteristics of a SAW device fabricated using the GaN layer grown by the method of the present invention. As shown in FIG. 12a, the SAW device in which the GaN layer grown by the conventional method is used as a piezoelectric substrate had a propagation velocity of 5,286 m/s, which was calculated from a cycle (λ=40 μm) at a center frequency of 132.15 MHz. In contrast, as shown in FIG. 12b, the SAW device in which the GaN layer grown by the method of the present invention is used as a piezoelectric substrate had a propagation velocity of 5,342 m/s at a center frequency of 133.57 MHz. This increase in propagation velocity is attributed to the fact that the GaN layer grown by the conventional method had a sheet resistance of about 3.7×10³ Ω/sq, whereas the GaN layer grown by the method of the present invention had a sheet resistance of about 1×10⁹ Ω/sq. Further, the GaN layer grown by the conventional method had an electromechanical coupling coefficient (K²) of 0.049%, whereas the GaN layer grown by the method of the present invention had an electromechanical coupling coefficient (K²) of 0.763%. The increased sheet resistance decreases the insertion loss, leading to an improvement in electrical properties.

Although the present invention has been described herein with reference to the foregoing embodiments and the accompanying drawings, the scope of the present invention is defined by the claims that follow. Accordingly, those skilled in the art will appreciate that various substitutions, modifications and changes are possible, without departing from the technical spirit of the present invention as disclosed in the accompanying claims.

As apparent from the above description, according to the method of the present invention, a highly semi-insulating GaN layer with high sheet resistance can be grown by controlling the growth temperature and time at the initial growth stage of the layer, without doping of dopants. In addition, the use of the highly semi-insulating GaN layer grown by the method of the present invention enables fabrication of HFETs and SAW devices having superior electrical properties.

1. A method for growing a semi-insulating GaN layer, comprising the steps of:
growing a buffer layer on a substrate at a first growth temperature;
growing a GaN layer on the buffer layer at a second growth temperature higher than the first growth temperature for a first growth time (a first growth step);
growing the GaN layer at increasing temperatures from the second growth temperature to a third growth temperature higher than the second growth temperature for a second growth time (a second growth step); and
growing the GaN layer at the third growth temperature for a third growth time (a third growth step).

2. The method according to claim 1, further comprising the step of annealing the buffer layer at the second growth temperature before the first growth step.

3. The method according to claim 1, wherein the second growth temperature is in the range of about 800° C. to about 950° C., and the third growth temperature is in the range of about 1,000° C. to 1,100° C.

4. The method according to claim 1, wherein the first growth time is about 3 minutes or less, and the second growth time is about 5 minutes or less.

5. An electronic device having a heterojunction structure formed by using a semi-insulating GaN layer grown by the method according to any one of claim 1.

6. A surface acoustic wave (SAW) device fabricated using a semi-insulating GaN layer grown by the method according to claim 1, as a piezoelectric substrate.
